(19) United States
(12) Patent Application Publication
(10) Pub. No.: US 2024/0053987 A1
(43) Pub. Date: Feb. 15, 2024

(54) MULTI-PORTED REGISTER FILE WITH CFETS

(71) Applicant: Intel Corporation, Santa Clara, CA (US)

(72) Inventors: Charles Augustine, Portland, OR (US); Seenivasan Subramaniam, Hillsboro, OR (US); Patrick Morrow, Portland, OR (US); Muhammad M. Khellah, Tigard, OR (US)

(21) Appl. No.: 17/887,154

(22) Filed: Aug. 12, 2022

(51) Int. Cl. G06F 9/30

(52) U.S. Cl. CPC G06F 9/30141; G06F 9/3012

(57) ABSTRACT

An apparatus, system, and method for register file circuits are provided. A register file circuit can include a first write bit line (WBL), a first P-channel metal oxide semiconductor (PMOS) transistor including a source coupled to the WBL, a first inverter including an input coupled to a drain of the first PMOS transistor, a second PMOS transistor including a source coupled to an output of the first inverter, and a second WBL (WBLB) coupled to a drain of the second PMOS transistor. 1R1W register file and 2R1W register file designs are provided.

### TECHNICAL FIELD

Embodiments pertain to improving die area of a multi-ported register file of a memory device.

### BACKGROUND

A prior multi-ported register file with one read line and one write line (1R1 W) includes six N-channel metal oxide semiconductor (NMOS) transistors and two P-channel metal oxide semiconductor (PMOS) transistors. A prior multi-ported register file with two read lines and one write line (2R1 W) includes eight NMOS transistors and two PMOS transistors. Both of these designs are highly asymmetric in that they both include NMOS transistor to PMOS transistors in ratios greater than 2:1. This asymmetry makes it difficult to exploit three-dimensional (3D) complementary field effect transistor (CFET) technology. As a result, register file area scaling is not feasible and larger memory dies are realized.

### BRIEF DESCRIPTION OF THE FIGURES

In the figures, which are not necessarily drawn to scale, like numerals may describe similar components in different views. Like numerals having different letter suffixes may represent different instances of similar components. The figures illustrate generally, by way of example, but not by way of limitation, various embodiments discussed in the present document.

FIG. 1 illustrates, by way of example, a block diagram of an embodiment of a 3D CFET.

FIG. 2 illustrates, by way of example, a circuit diagram of an embodiment of a 1R1 W register file with six NMOS and two PMOS transistors.

FIG. 3 illustrates, by way of example, a circuit diagram of an embodiment of a 2R1 W register file with eight NMOS and two PMOS transistors.

FIG. 4 illustrates, by way of example, a circuit diagram of an embodiment of a 1R1 W register file with balanced NMOS and PMOS transistors.

FIG. 5 illustrates, by way of example, a layout diagram of an embodiment of a register file that operates as the register file that has an unbalanced number of PMOS and NMOS transistors.

FIG. 6 illustrates, by way of example, a layout diagram of an embodiment of a front side portion of a register file that operates as the register file that has a balanced number of PMOS and NMOS transistors and exploits a CFET configuration.

FIG. 7 illustrates, by way of example, a layout diagram of an embodiment of a back side portion of the register file that operates as the register file 400 that has the balanced number of PMOS and NMOS transistors and exploits the CFET configuration.

FIG. 8 illustrates, by way of example, a circuit diagram of an embodiment of a 2R1 W register file that benefits from CFET technology area gains.

FIG. 9 illustrates, by way of example, a layout diagram for a “baseline” 2R1 W register file memory.

FIG. 10 illustrates, by way of example, a layout diagram of a front side of a 2R1 W register file that better uses CFET technology to reduce area and improve electrical performance.

FIG. 11 illustrates, by way of example, a layout diagram of a back side of the 2R1 W register file that better uses CFET technology.

FIG. 12 illustrates, by way of example, a method of making an improved register file cell.

FIG. 13 illustrates, by way of example, a block diagram of an embodiment of a machine (e.g., a computer system) in which the register file, a method, or a combination thereof or another circuit or method discussed herein can be used.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Demand for memories has been increasing and on-die caches are employed in high-performance processors are increasing in size. This demand is further amplified due to the integration of accelerators (e.g., tile matrix multiply (TMUL), advanced vector extensions (AVX), vision processing units (VPU), or the like) that support new workloads. In addition to six transistor (6T) static random access memories (SRAMs), multi-ported register files (RF) also contribute significant die area, especially for graphics processing unit (GPU) execution units and for central processing unit (CPU) instruction caches. Similar to 6T SRAM, multi-ported RF also faces scalability issues due to lithography challenges associated with process scaling even though standard logic cells continued to scale across technology generations.

Three dimensional (3D) complementary field effect transistors (CFET) has been used to improve transistor scaling where PMOS and NMOS transistors are vertically integrated in the same footprint. 3D CFET provides up to 50% area scaling in the area spanned by CMOS logic gates if the number of PMOS and NMOS transistors is balanced. However, a conventional multi-ported RF has an asymmetric number of PMOS and NMOS access transistors which do not fit well to benefit from CFET technology. For example, an eight transistor 1R1 W RF cell with one read port and one write port has six NMOS and two PMOS transistors. PMOS to NMOS transistor ratio skews even further in 2R1 W with two read and one write ports. A conventional 2R1 W RF includes eight NMOS and two PMOS transistors. Embodiments provide RF architectures with a more balanced number of NMOS and PMOS transistors so that the RF architectures can efficiently exploit CFET technology to provide improved density through reduced x-y die area.

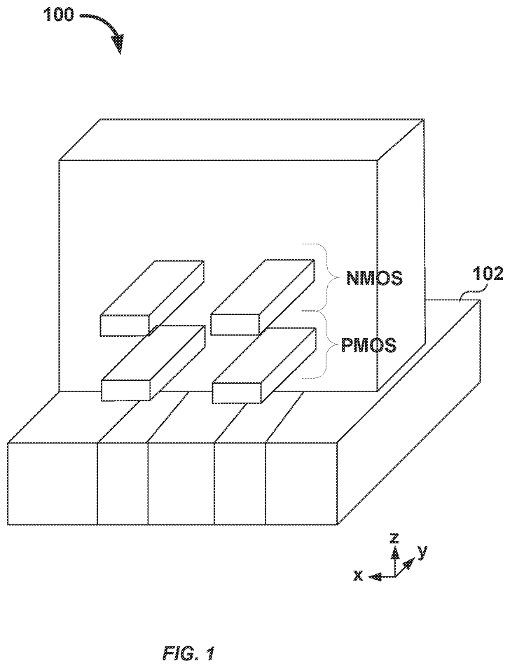

FIG. 1 illustrates, by way of example, a block diagram of an embodiment of a 3D CFET 100. The CFET 100 includes one or more PMOS transistors formed over a substrate 102. The CFET 100 further includes one or more NMOS transistors formed over the PMOS transistors. Note that the PMOS transistors can be formed over or under the NMOS transistors, but it is more common that the PMOS transistors are situated between the NMOS transistors and the substrate 102. The CFET 100 includes a reduced x-y area as compared to other transistor configurations, but at the expense of an increased height in z.

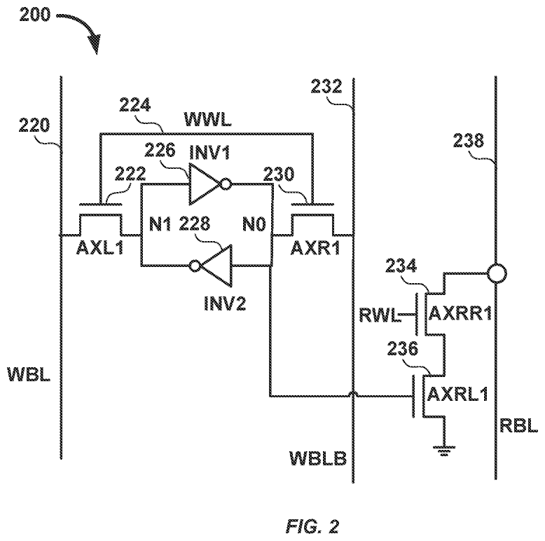

FIG. 2 illustrates, by way of example, a circuit diagram of an embodiment of a 1R1 W register file 200 with six NMOS and two PMOS transistors. The NMOS transistors include AXL1 222, AXR1 230, AXRL1 236, and AXRR1 234, as well as a single NMOS transistor in each of the inverters INV1 226 and INV2 228. The PMOS transistors include a single PMOS transistor in each of the inverters INV1 226 and INV2 228. A first write bitline (WBL) 220 controls whether the register file writes to a memory and controls a source of the transistor AXL1 222. A write word line (WWL) 224 controls gates of the transistors AXL1 222 and AXR1 230. A drain of the transistor AXL1 222 is coupled to an input of the INV1 226 and an output of the INV2 228. An output of the INV1 226 is coupled to the input of the INV2 228. An output of the INV2 228 is coupled to the input of the INV1 226. A second WBL (WBLB) is coupled to a drain of the AXR1 230. A gate of the AXRL1 236 is controlled by the output of the INV1 226. A source of the AXRL1 236 is coupled to ground. A gate of the AXRR1 234 is controlled by a read word line (RWL). The drain of the AXRL1 236 is coupled to a source of the AXRR1 234. A drain of the AXRR1 234 controls a state of a read bit line 238. The register file 200 has an unbalanced number of NMOS and PMOS transistors such that manufacture of the register file 200 cannot exploit CFET technology to reduce the x-y area consumed by the circuit.

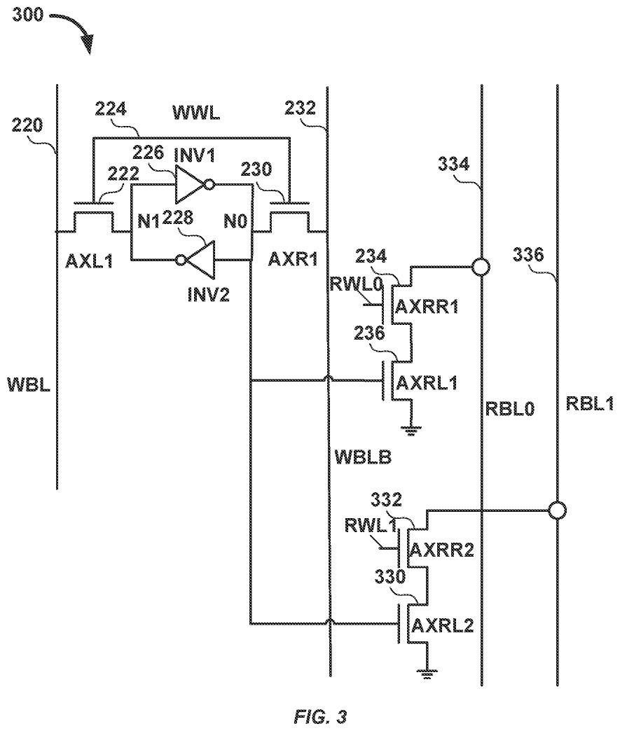

FIG. 3 illustrates, by way of example, a circuit diagram of an embodiment of a 2R1 W register file 300 with eight NMOS and two PMOS transistors. The NMOS transistors include AXL1 222, AXR1 230, AXRL1 236, AXRR1 234, AXRL2 330, and AXRR2 332 as well as a single NMOS transistor in each of the inverters INV1 226 and INV2 228. The PMOS transistors include a single PMOS transistor in each of the inverters INV1 226 and INV2 228. The register file 300 as illustrated is similar to the register file 200 of FIG. 2 with the register file 300 including an additional set of NMOS transistors AXRL2 330 and AXRR2 332 that drive a second read bit line 336. The register file 300 also includes an additional read word line (RWL1). The gate of AXRR1 234 is thus driven by a first RWL (RWL0) and a gate of AXRR2 332 is driven by a second RWL (RWL1). A gate of the AXRL2 330 is controlled by the output of the INV1 226. A source of the AXRL1 330 is coupled to the ground. A drain of the AXRL2 is coupled to a source of the AXRR2 332. A source of the AXRL2 330 is coupled to the ground. A drain of the AXRR2 332 is coupled to a second RBL (RBL1 336). A drain of the AXRR1 234 is coupled to a first RBL (RBL0 334). The register file 300 has an unbalanced number of NMOS and PMOS transistors such that production of the register file 300 cannot exploit CFET technology to reduce the x-y area consumed by the circuit.

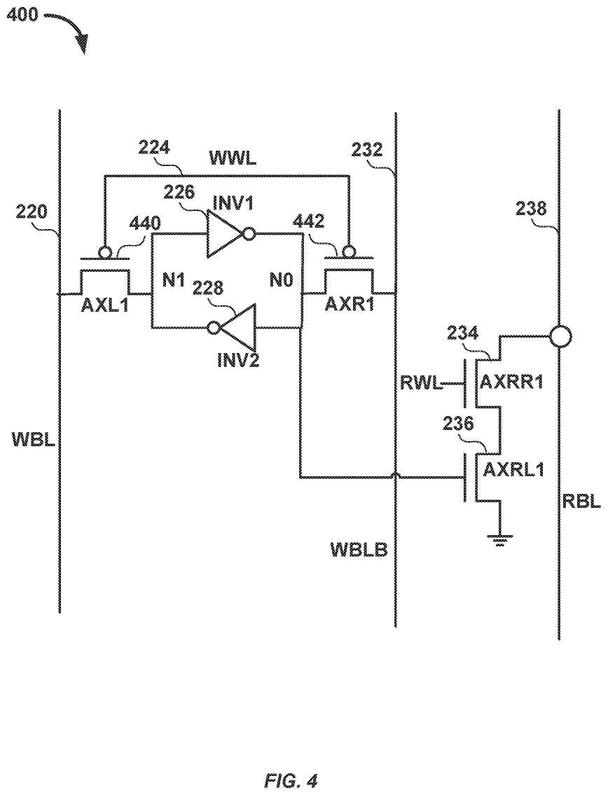

FIG. 4 illustrates, by way of example, a circuit diagram of an embodiment of a 1R1 W register file 400 with balanced NMOS and PMOS transistors. The register file 400 is similar to the register file 200 of FIG. 2 with PMOS transistors AXL1 440 and AXR1 442 in place of NMOS transistors AXL1 222 and AXR1 230, respectively. By replacing the NMOS transistors AXL1 222 and AXR1 230 with PMOS transistors AXL1 440 and AXR1 442, there are four PMOS transistors and four NMOS transistors. The PMOS transistors are AXL1 440 and AXR1 442, as well as the INV1 226 and the INV2 228 each providing another single PMOS transistor each, for a total of four. The NMOS transistors are AXRR1 234 and AXRL1 236 along with the INV1 226 and the INV2 228 each providing another single NMOS transistor each, for a total of four. The ratio of the PMOS transistors to NMOS transistors in the register file 400 is thus 1:1.

The signal logic to properly operate the register file 200 and the register file 400 is different. This is due, at least in part, to the changing two NMOS transistors to PMOS transistors. Table 1 summarizes the control logic for both the register file 200 and the register file 400.

TABLE 1
Control signals for read, write, and retention operations for the register
file 200 (“baseline”) and the register file 400 (“proposed”) 1R1W
bit-cell. Only WWL signal polarity is different between the two.

| | | | WWL | | | |
|---|---|---|---|---|---|---|
| | WBL | WBLB | Baseline | Proposed | RBL | RWL |
| Write 0 | VCC | 0 | VCC | 0 | VCC | 0 |
| Write 1 | 0 | VCC | VCC | 0 | VCC | 0 |
| Read 1 | VCC | VCC | 0 | VCC | 0 | VCC |
| Read 0 | VCC | VCC | 0 | VCC | VCC | VCC |
| Retention | VCC | VCC | 0 | VCC | VCC | 0 |

A material buildup for each of the register files 200 and 400 is now provided to aid in understanding the area savings provided by the register file 400.

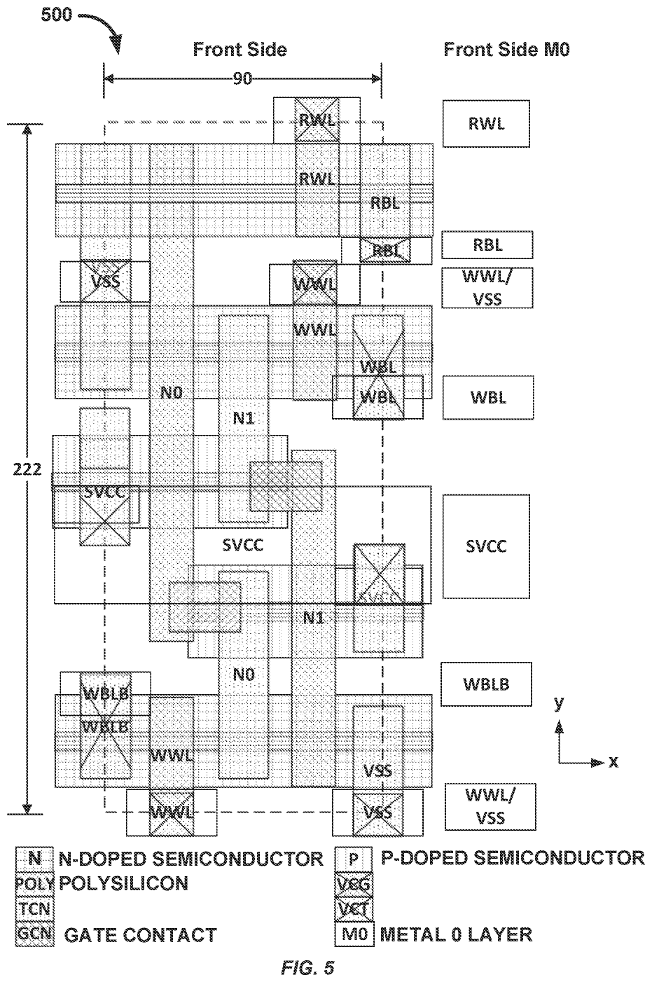

FIG. 5 illustrates, by way of example, a layout diagram of an embodiment of a register file 500 that operates as the register file 200 that has an unbalanced number of PMOS and NMOS transistors. The labels on parts of the register file 500 are consistent with the labels on the register file 200. As was noted previously, the register file includes 6 NMOS and 2 PMOS transistors.

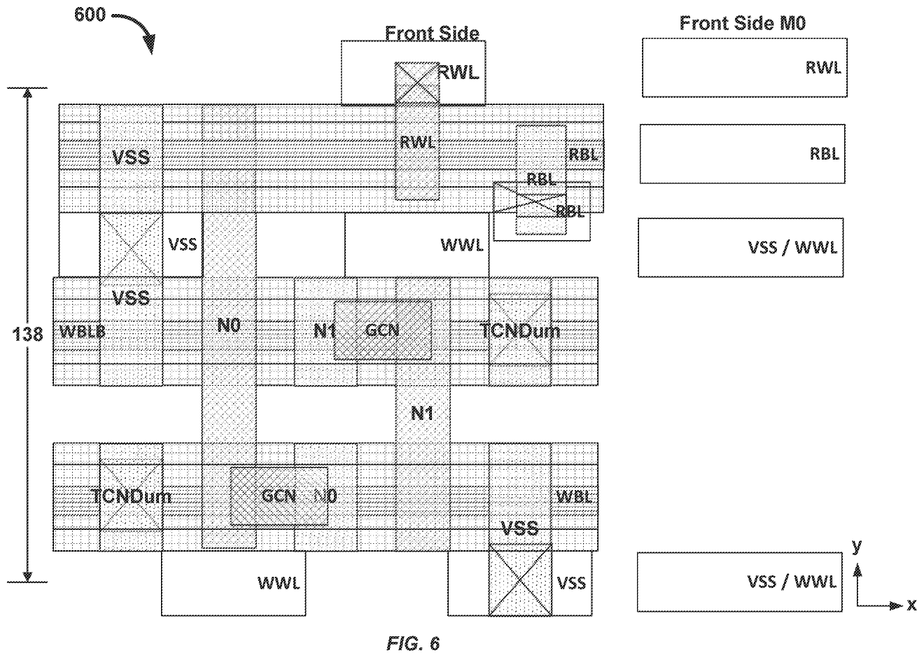

FIG. 6 illustrates, by way of example, a layout diagram of an embodiment of a front side portion of a register file 600 that operates as the register file 400 that has a balanced number of PMOS and NMOS transistors and exploits a CFET configuration. The layers of all layout diagrams are consistent such that the legend on FIG. 4 applies to all layout diagrams.

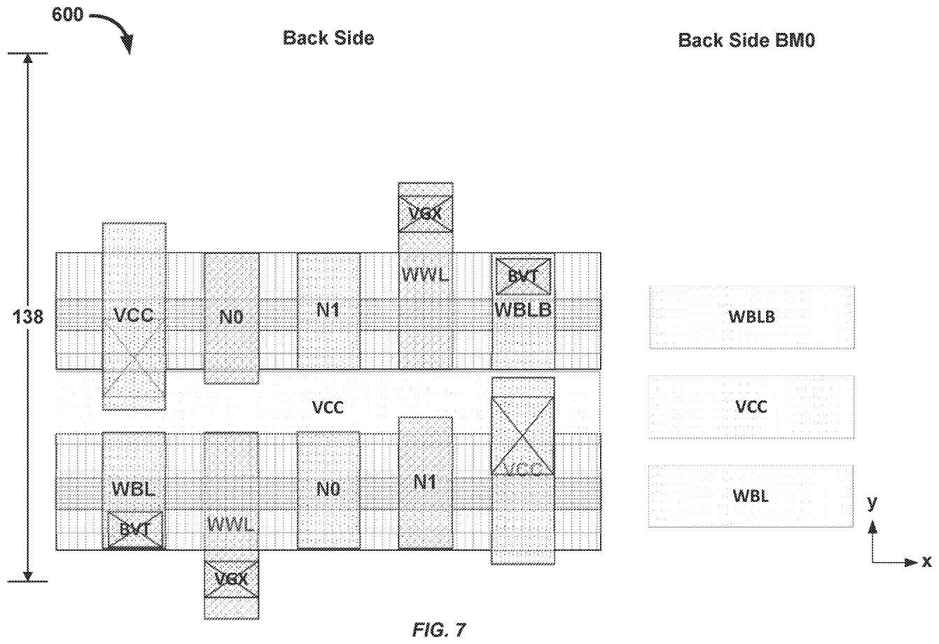

FIG. 7 illustrates, by way of example, a layout diagram of an embodiment of a back side portion of the register file 600 that operates as the register file 400 that has the balanced number of PMOS and NMOS transistors and exploits the CFET configuration. The register file 600 is reduced in extent in y by (222 nm-138 nm)=84 nm. The dense multi-ported register file 400 that uses CFETs (as shown in FIGS. 6-7) can be used in any system on chip (SoC) and especially beneficial where density, performance, and power consumption are bottlenecks. The proposed CFET based 1R1 W implementation in FIGS. 4, 6, and 7 alleviates the scaling challenge associated with SRAM memory. The register file 400 whose layout is shown in FIGS. 6 and 7 provides about 38% area savings for the 1R1 W bit-cell.

Due to the asymmetric nature of NMOS and PMOS with the with 6 NMOSs and 2 PMOSs for the register file 200, the layout height (as shown in FIG. 5) is 222 nm and most of the area is devoted to NMOS diffusion and MO connectivity and back-side MO (BMO) and PMOS diffusion is under-utilized. The layout in FIG. 5 does not take advantage of 3D CFET technology, with NMOS stacked on top of PMOS, since the bit-cell area is not dominated by front-end (transistor) scaling but rather by non-scalability of back-end (routing) resources like the two Gate Contacts (GCNs) used to make the poly-to-diffusion cross-coupled N0 and N1 internal 1R1 W node connections. For the 1R1 W in FIG. 4, a more area efficient layout can be realized as presented in FIGS. 6 and 7. Compared to baseline CFET 1R1 W (FIG. 4), the layout height decreased from 222 nm to 138 nm resulting in 38% area saving thanks to using PMOS write transistors instead of NMOS. The technique of using a PMOS write device, allows for removal of the NMOS transistor (stacked on top of the PMOS write device), oxidizing the channel, and using resultant space for the GCNs connecting the cross-coupled nodes. This optimization together with stacking of the 2 NMOSs and 2 PMOSs of the 2 inverters of the 1R1 W cell, reducing the cell area significantly. Circuit operation of baseline 1R1 W and proposed 1R1 W is summarized in Table 1. The main difference between the two is the inversion of Write WL (WWL) polarity requiring a small change in write word line (WWL) driver design.

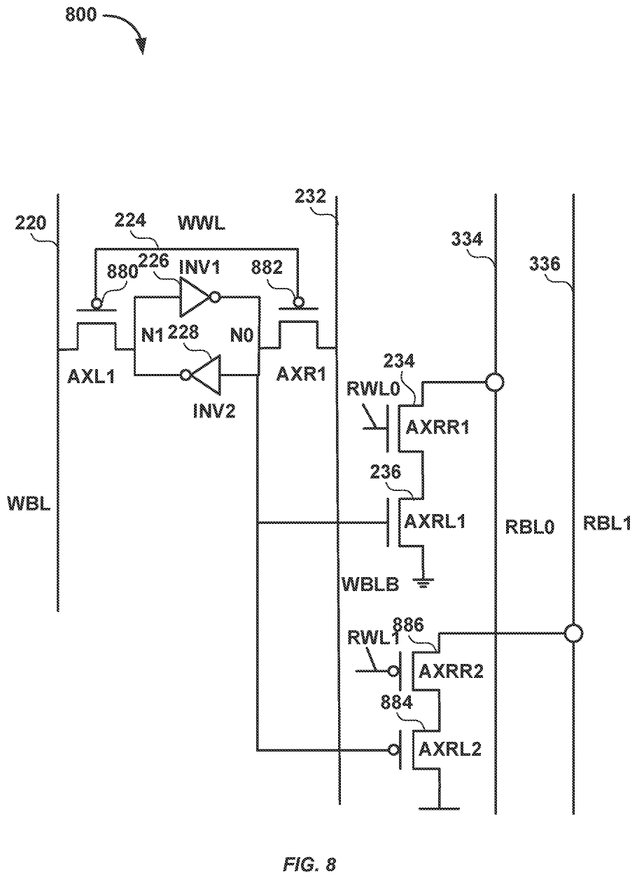

FIG. 8 illustrates, by way of example, a circuit diagram of an embodiment of a 2R1 W register file 800 that benefits from CFET technology area gains. The register file 800 improves upon the register file 300 by changing the NMOS transistors 222 and 230 to PMOS transistors 880 and 882, respectively, and changing the NMOS transistors 330 and 332 to PMOS transistors 884 and 886, respectively. In addition the source of the transistor AXRL2 is coupled to the supply instead of the ground.

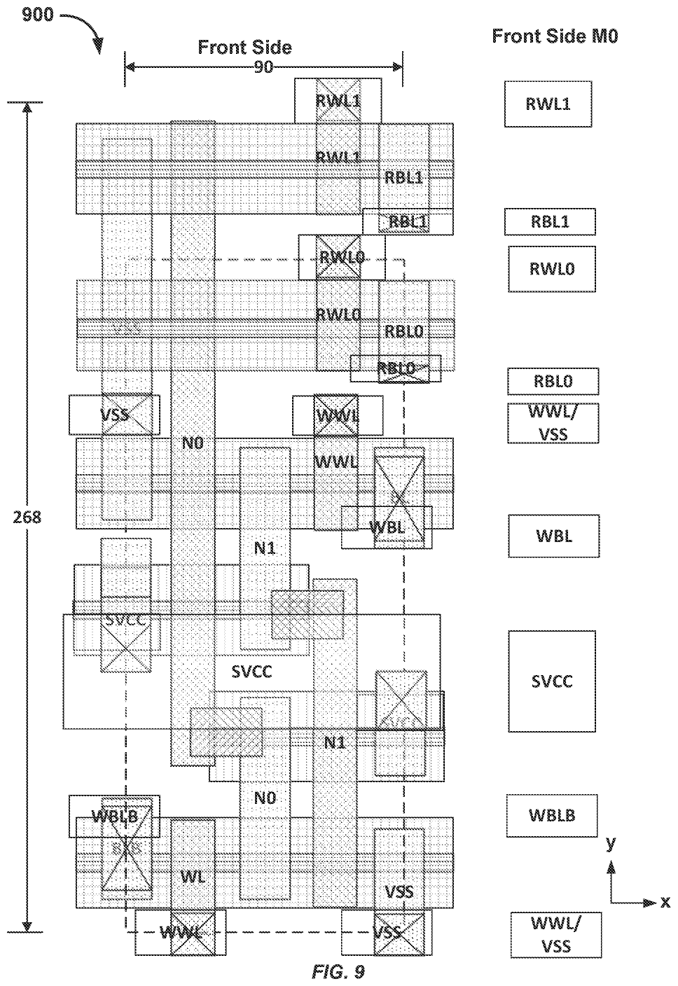

FIG. 9 illustrates, by way of example, a layout diagram for a “baseline” 2R1 W register file 900 memory. Since there are two additional NMOS transistors in a baseline 2R1 W (see FIG. 3) as compared to a baseline 1R1 W (see FIG. 2), the layout of the 2R1 W is further stretched in the y-direction to accommodate one more NMOS diffusion row for the second read port, resulting in 268 nm of cell height. Similar to the 1R1 W cell of FIG. 2, the under-utilization of PMOS and back-side metal resources, while also not taking full advantage of the stacked CFET structure, result in layout efficiency losses.

In the 2R1 W register file 800 of FIG. 8, besides using the PMOS write transistors 880, 882 that provide advantages similar to the proposed 1R1 W cell 400 with the same feature, the 2R1 W register file 800 also features complementary read ports with one read port based on NMOS devices, while the second read port is based on PMOS devices 884, 886.

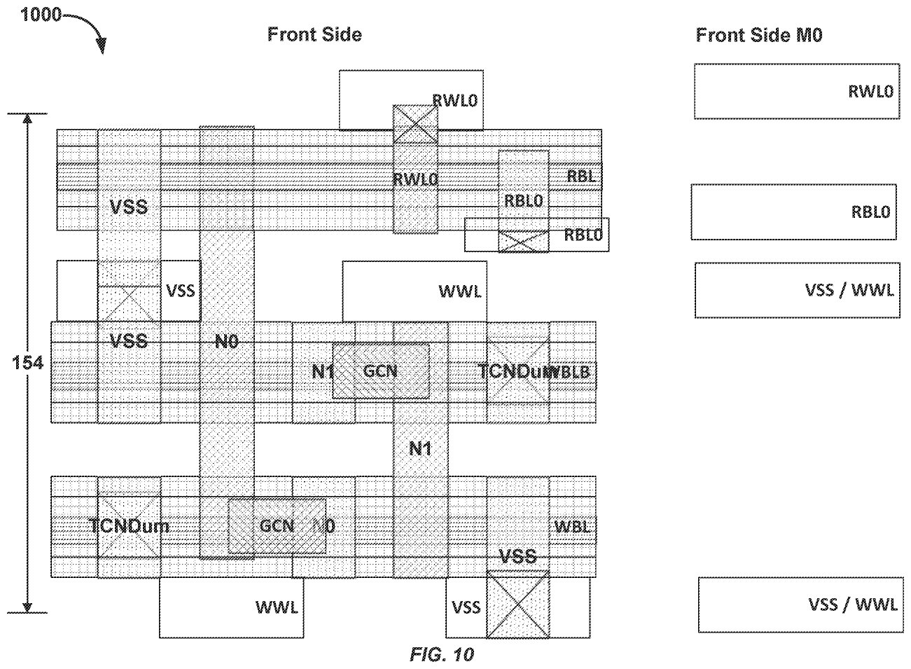

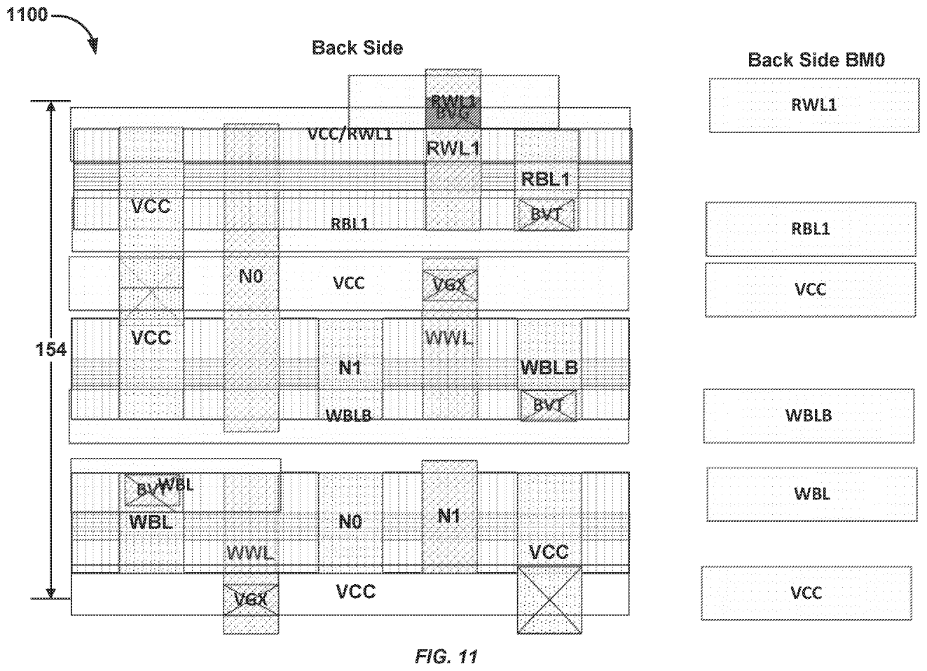

FIG. 10 illustrates, by way of example, a layout diagram of a front side of a 2R1 W register file 1000 that better uses CFET technology to reduce area and improve electrical performance. FIG. 11 illustrates, by way of example, a layout diagram of a back side of the 2R1 W register file 1000 that better uses CFET technology. The register file layout in FIGS. 10 and 11 performs the operations of the reference 800 of FIG. 8. The register file 800 enables a more efficient utilization of a CFET stack, with the NMOS read port located right on top of the PMOS port as shown in FIGS. 10 and 11. The register file 800 also helps maximizes a utilization of back side metal 0 (MO) resources as shown in FIG. 11. With the improved utilization, the cell height is reduced by about 43% from 268 nm in the baseline design (see FIG. 9) to 154 nm (see FIGS. 10 and 11).

A summary of driver circuit changes for the 2R1 W register file 800 is presented in Table 2 below. In addition to the polarity inversion of WWL required for write access as was discussed regarding the 1R1 W register file 400, the 2R1 W register file 800 includes an inversion of RWL polarity during read from the PMOS port (RWL1), and also has a pre-discharge of the RBL before read from the PMOS port (RBL1) versus pre-charge RBL in baseline NMOS port.

TABLE 2
Control signals for read, write, and retention operations for baseline
(register file 300) and improved (register file 800) 2R1W cells.

| | | | WWL | | | | RBL1 | | RWL1 | |
|---|---|---|---|---|---|---|---|---|---|---|
| | WBL | WBLB | Baseline | Proposed | RBL0 | RWL0 | Baseline | Proposed | Baseline | Proposed |
| Write 0 | VCC | 0 | VCC | 0 | VCC | 0 | VCC | 0 | 0 | VCC |
| Write 1 | 0 | VCC | VCC | 0 | VCC | 0 | VCC | 0 | 0 | VCC |
| BL0: Read 1 | VCC | VCC | 0 | VCC | 0 | VCC | VCC | 0 | 0 | VCC |
| BL0: Read 0 | VCC | VCC | 0 | VCC | VCC | VCC | VCC | 0 | 0 | VCC |
| BL1: Read 1 | VCC | VCC | 0 | VCC | VCC | 0 | 0 | 0 | VCC | 0 |
| BL1: Read 0 | VCC | VCC | 0 | VCC | VCC | 0 | VCC | VCC | VCC | 0 |
| Retention | VCC | VCC | 0 | VCC | VCC | 0 | VCC | 0 | 0 | VCC |

In addition to the area benefit, the proposed 2R1 W register file 800 reduces a worst-case bit-line leakage. This is because one of the two ports in the register file 800 will always have a stacking effect which happens in the PMOS read port when the NO node stores “1” and in the NMOS read port when the NO node stores “0” compared to baseline 2R1 W with worst case read BL leakage occurring when just NO nodes stores “1”. Using the PMOS transistors in the register file 800 thus eliminates a stacking effect from both read and write ports and provides a corresponding leakage decrease.

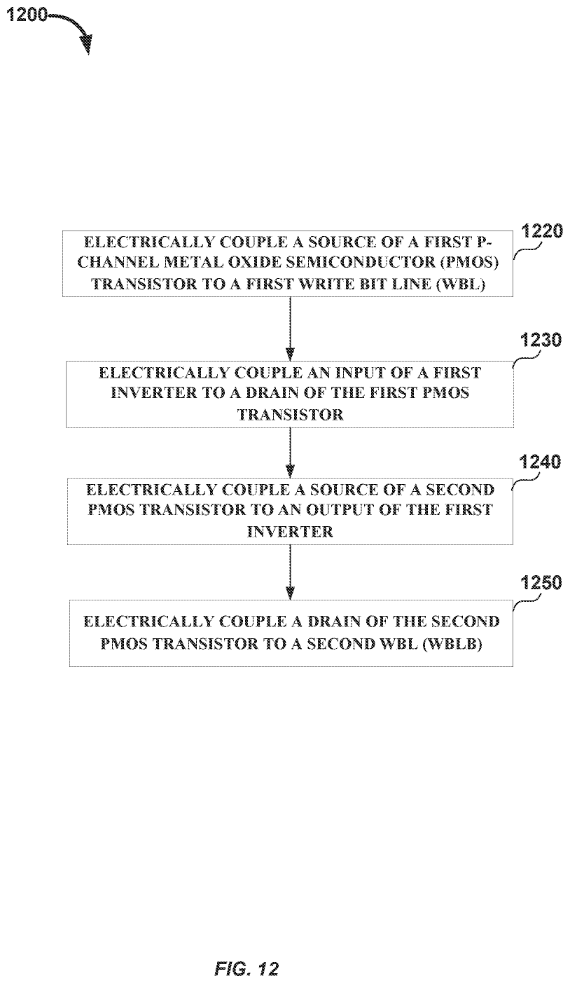

FIG. 12 illustrates, by way of example, a method 1200 of making an improved register file cell. The method 1200 as illustrated includes electrically coupling a source of a first P-channel metal oxide semiconductor (PMOS) transistor to a first write bit line (WBL), at operation 1220; electrically coupling an input of a first inverter to a drain of the first PMOS transistor, at operation 1230; electrically coupling a source of a second PMOS transistor to an output of the first inverter, at operation 1240; and electrically coupling a drain of the second PMOS transistor to a second WBL (WBLB), at operation 1250.

The method 1200 can further include electrically coupling a gate of a first N-channel metal oxide semiconductor (NMOS) transistor to the output of the first inverter. The method 1200 can further include electrically coupling a source of a second NMOS transistor to a drain of the first NMOS transistor.

The method 1200 can further include electrically coupling a first read bit line to a drain of the second NMOS transistor. The method 1200 can further include electrically coupling a gate of a third PMOS transistor to the output of the first inverter. The method 1200 can further include electrically coupling a source of a fourth PMOS transistor to a drain of the third PMOS transistor. The method 1200 can further include electrically coupling a first read bit line (RBL0) to a drain of the second NMOS transistor. The method 1200 can further include electrically coupling a second read bit line (RBL1) to a drain of the fourth PMOS transistor.

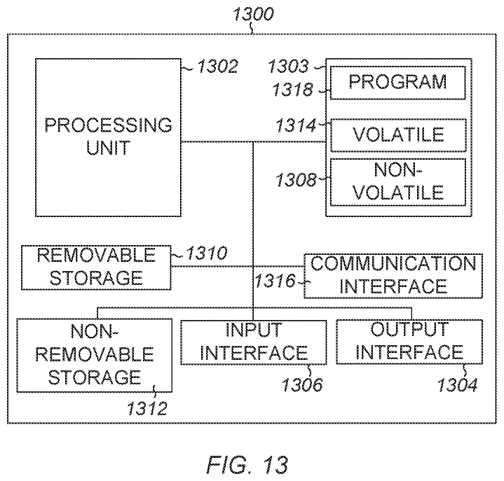

FIG. 13 illustrates, by way of example, a block diagram of an embodiment of a machine 1300 (e.g., a computer system) in which the register file 400, 800, the method 1200, or a combination thereof or another circuit or method discussed herein can be used. The register file 400, 800 or other register file can be electrically coupled, such as by a WBL, RBL, WWL, RWL, a combination thereof, to the memory 1303 or be an integral part of the memory 1303. One example machine 1230 (in the form of a computer), may include a processing unit 1302, memory 1303, removable storage 1310, and non-removable storage 1312. Although the example computing device is illustrated and described as machine 1300, the computing device may be in different forms in different embodiments. Further, although the various data storage elements are illustrated as part of the machine 1300, the storage may also or alternatively include cloud-based storage accessible via a network, such as the Internet.

Memory 1303 may include volatile memory 1314 and non-volatile memory 1308. The machine 1300 may include—or have access to a computing environment that includes—a variety of computer-readable media, such as volatile memory 1314 and non-volatile memory 1308, removable storage 1310 and non-removable storage 1312. Computer storage includes random access memory (RAM), read only memory (ROM), erasable programmable read-only memory (EPROM) & electrically erasable programmable read-only memory (EEPROM), flash memory or other memory technologies, compact disc read-only memory (CD ROM), Digital Versatile Disks (DVD) or other optical disk storage, magnetic cassettes, magnetic tape, magnetic disk storage or other magnetic storage devices capable of storing computer-readable instructions for execution to perform functions described herein.

The machine 1300 may include or have access to a computing environment that includes input 1306, output 1304, and a communication connection 1316. Output 1304 may include a display device, such as a touchscreen, that also may serve as an input device. The input 1306 may include one or more of a touchscreen, touchpad, mouse, keyboard, camera, one or more device-specific buttons, one or more sensors integrated within or coupled via wired or wireless data connections to the machine 1300, and other input devices. The computer may operate in a networked environment using a communication connection to connect to one or more remote computers, such as database servers, including cloud-based servers and storage. The remote computer may include a personal computer (PC), server, router, network PC, a peer device or other common network node, or the like. The communication connection may include a Local Area Network (LAN), a Wide Area Network (WAN), cellular, Institute of Electrical and Electronics Engineers (IEEE) 802.11 (Wi-Fi), Bluetooth, or other networks.

Computer-readable instructions stored on a computer-readable storage device are executable by the processing unit 1302 (sometimes called processing circuitry) of the machine 1300. A hard drive, CD-ROM, and RAM are some examples of articles including a non-transitory computer-readable medium such as a storage device. For example, a computer program 1318 may be used to cause processing unit 1202 to perform one or more methods or algorithms described herein.

Note that the term “circuitry” or “circuit” as used herein refers to, is part of, or includes hardware components, such as transistors, resistors, capacitors, diodes, inductors, amplifiers, oscillators, switches, multiplexers, logic gates (e.g., AND, OR, XOR), power supplies, memories, or the like, such as can be configured in an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” or “circuit” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry”, “processing circuitry”, or “processor” as used herein thus refers to, is part of, or includes circuitry capable of sequentially and automatically carrying out a sequence of arithmetic or logical operations, or recording, storing, and/or transferring digital data. These terms may refer to one or more application processors, one or more baseband processors, a physical central processing unit (CPU), a single- or multi-core processor, and/or any other device capable of executing or otherwise operating computer-executable instructions, such as program code, software modules, and/or functional processes.

### Additional Notes and Examples

Example 1 includes a register file circuit comprising, a first write bit line (WBL), a first P-channel metal oxide semiconductor (PMOS) transistor including a source coupled to the WBL, a first inverter including an input coupled to a drain of the first PMOS transistor, a second PMOS transistor including a source coupled to an output of the first inverter, and a second WBL (WBLB) coupled to a drain of the second PMOS transistor.

In Example 2, Example 1 further includes a first N-channel metal oxide semiconductor (NMOS) transistor including a gate coupled to the output of the first inverter, and a second NMOS transistor including a source coupled to a drain of the first NMOS transistor.

In Example 3, Example 2 further includes a first read bit line coupled to a drain of the second NMOS transistor.

In Example 4, at least one of Examples 2-3 further includes a third PMOS transistor including a gate coupled to the output of the first inverter, and a fourth PMOS transistor including a source coupled to a drain of the third PMOS transistor.

In Example 5, Example 4 further includes a first read bit line coupled to a drain of the second NMOS transistor, and a second read bit line coupled to a drain of the fourth PMOS transistor.

In Example 6, at least one of Examples 2-5 further includes a second inverter including an input coupled to an output of the first inverter and an output coupled to a drain of the first NMOS transistor.

In Example 7, Example 6 further includes, wherein a gate of the first PMOS transistor and a gate of the second PMOS transistor are coupled to a write word line.

Example 8 includes a memory device comprising a memory, a register file comprising a first write bit line (WBL), a first P-channel metal oxide semiconductor (PMOS) transistor including a source coupled to the WBL, a first inverter including an input coupled to a drain of the first PMOS transistor, a second PMOS transistor including a source coupled to an output of the first inverter, and a second WBL (WBLB) coupled to a drain of the second PMOS transistor.

In Example 9, Example 8 further includes, wherein the memory device is a static random access memory (SRAM).

In Example 10, at least one of Examples 8-9 further includes, wherein the register file further comprises a first N-channel metal oxide semiconductor (NMOS) transistor including a gate coupled to the output of the first inverter, and a second NMOS transistor including a source coupled to a drain of the first NMOS transistor.

In Example 11, Example 10 further includes, wherein the register file further comprises a first read bit line coupled to a drain of the second NMOS transistor.

In Example 12, at least one of Examples 10-11 further includes, wherein the register file further comprises a third PMOS transistor including a gate coupled to the output of the first inverter, and a fourth PMOS transistor including a source coupled to a drain of the third PMOS transistor.

In Example 13, Example 12 further includes, wherein the register file further comprises a first read bit line coupled to a drain of the second NMOS transistor, and a second read bit line coupled to a drain of the fourth PMOS transistor.

In Example 14, at least one of Examples 10-13 further includes, wherein the register file further comprises a second inverter including an input coupled to an output of the first inverter and an output coupled to a drain of the first NMOS transistor.

In Example 15, Example 14 further includes, wherein a gate of the first PMOS transistor and a gate of the second PMOS transistor are coupled to a write word line.

Example 16 includes a method for register file generation, the method comprising electrically coupling a source of a first P-channel metal oxide semiconductor (PMOS) transistor to a first write bit line (WBL), electrically coupling an input of a first inverter to a drain of the first PMOS transistor, electrically coupling a source of a second PMOS transistor to an output of the first inverter, and electrically coupling a drain of the second PMOS transistor to a second WBL (WBLB).

In Example 17, Example 16 further includes electrically coupling a gate of a first N-channel metal oxide semiconductor (NMOS) transistor to the output of the first inverter, and electrically coupling a source of a second NMOS transistor to a drain of the first NMOS transistor.

In Example 18, Example 17 further includes electrically coupling a first read bit line to a drain of the second NMOS transistor.

In Example 19, at least one of Examples 17-18 further includes electrically coupling a gate of a third PMOS transistor to the output of the first inverter, and electrically coupling a source of a fourth PMOS transistor to a drain of the third PMOS transistor.

In Example 20, Example 19 further includes electrically coupling a first read bit line (RBL0) to a drain of the second NMOS transistor, and electrically coupling a second read bit line (RBL1) to a drain of the fourth PMOS transistor.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The Abstract of the Disclosure is provided to comply with 37 C.F.R. § 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A register file circuit comprising:
a first write bit line (WBL);
a first P-channel metal oxide semiconductor (PMOS) transistor including a source coupled to the WBL;
a first inverter including an input coupled to a drain of the first PMOS transistor;
a second PMOS transistor including a source coupled to an output of the first inverter; and
a second WBL (WBLB) coupled to a drain of the second PMOS transistor.

2. The register file circuit of claim 1, further comprising:
a first N-channel metal oxide semiconductor (NMOS) transistor including a gate coupled to the output of the first inverter; and
a second NMOS transistor including a source coupled to a drain of the first NMOS transistor.

3. The register file of claim 2, further comprising a first read bit line coupled to a drain of the second NMOS transistor.

4. The register file of claim 2, further comprising:
a third PMOS transistor including a gate coupled to the output of the first inverter; and
a fourth PMOS transistor including a source coupled to a drain of the third PMOS transistor.

5. The register file of claim 4, further comprising:
a first read bit line coupled to a drain of the second NMOS transistor; and
a second read bit line coupled to a drain of the fourth PMOS transistor.

6. The register file of claim 2, further comprising a second inverter including an input coupled to an output of the first inverter and an output coupled to a drain of the first NMOS transistor.

7. The register file of claim 6, wherein a gate of the first PMOS transistor and a gate of the second PMOS transistor are coupled to a write word line.

8. A memory device comprising:
a memory;
a register file comprising:
a first write bit line (WBL);
a first P-channel metal oxide semiconductor (PMOS) transistor including a source coupled to the WBL;
a first inverter including an input coupled to a drain of the first PMOS transistor;
a second PMOS transistor including a source coupled to an output of the first inverter; and
a second WBL (WBLB) coupled to a drain of the second PMOS transistor.

9. The memory device of claim 8, wherein the memory device is a static random access memory (SRAM).

10. The memory device of claim 8, wherein the register file further comprises:
a first N-channel metal oxide semiconductor (NMOS) transistor including a gate coupled to the output of the first inverter; and
a second NMOS transistor including a source coupled to a drain of the first NMOS transistor.

11. The memory device of claim 10, wherein the register file further comprises a first read bit line coupled to a drain of the second NMOS transistor.

12. The memory device of claim 10, wherein the register file further comprises:
a third PMOS transistor including a gate coupled to the output of the first inverter; and
a fourth PMOS transistor including a source coupled to a drain of the third PMOS transistor.

13. The memory device of claim 12, wherein the register file further comprises:
a first read bit line coupled to a drain of the second NMOS transistor; and
a second read bit line coupled to a drain of the fourth PMOS transistor.

14. The memory device of claim 10, wherein the register file further comprises a second inverter including an input coupled to an output of the first inverter and an output coupled to a drain of the first NMOS transistor.

15. The memory device of claim 14, wherein a gate of the first PMOS transistor and a gate of the second PMOS transistor are coupled to a write word line.

16. A method for register file generation, the method comprising:
electrically coupling a source of a first P-channel metal oxide semiconductor (PMOS) transistor to a first write bit line (WBL);
electrically coupling an input of a first inverter to a drain of the first PMOS transistor;
electrically coupling a source of a second PMOS transistor to an output of the first inverter; and
electrically coupling a drain of the second PMOS transistor to a second WBL (WBLB).

17. The method of claim 16, further comprising:
electrically coupling a gate of a first N-channel metal oxide semiconductor (NMOS) transistor to the output of the first inverter; and
electrically coupling a source of a second NMOS transistor to a drain of the first NMOS transistor.

18. The method of claim 17, further comprising electrically coupling a first read bit line to a drain of the second NMOS transistor.

19. The method of claim 17, further comprising:
electrically coupling a gate of a third PMOS transistor to the output of the first inverter; and
electrically coupling a source of a fourth PMOS transistor to a drain of the third PMOS transistor.

20. The method of claim 19, further comprising:
electrically coupling a first read bit line (RBL0) to a drain of the second NMOS transistor; and
electrically coupling a second read bit line (RBL1) to a drain of the fourth PMOS transistor.
